(19) United States
(12) Patent Application Publication
(10) Pub. No.: US 2007/0218672 A1
(43) Pub. Date: Sep. 20, 2007

(54) IMMERSION PLATING TREATMENT FOR METAL-METAL INTERCONNECTS

(75) Inventor: Simon J. Jacobs, Lucas, TX (US)

Correspondence Address: TEXAS INSTRUMENTS INCORPORATED, P O BOX 655474, M/S 3999, DALLAS, TX, 75265, US

(73) Assignee: Texas Instruments, Incorporated, Dallas, TX (US)

(21) Appl. No.: 11/613,482

(22) Filed: Dec. 20, 2006

Related U.S. Application Data
(60) Provisional application No. 60/782,644, filed on Mar. 15, 2006.

(51) Int. Cl. H01L 21/44

(52) U.S. Cl. 438/597

(57) ABSTRACT

The present disclosure provides a method for manufacturing an interconnect in a semiconductor device, a method for manufacturing a digital micromirror device, a digital micromirror device and a method for manufacturing a projection display system. The method for manufacturing the digital micromirror device, without limitation, may include forming a first metal layer over a substrate and subjecting the first metal layer to an immersion deposition process, the immersion deposition process forming a passivating layer over the first metal layer. This method may also include forming a spacer layer over the first metal layer, the spacer layer having one or more openings therein, and forming a second metal layer over the spacer layer and in the one or more openings, the second metal layer contacting the passivating layer.

### CROSS-REFERENCE TO PROVISIONAL APPLICATION

This application claims the benefit of U.S. Provisional Application No. 60/782,644 entitled “IMMERSION PLATING TREATMENT FOR METAL-METAL INTERCONNECTS” to Simon J. Jacobs, et al., filed on Mar. 15, 2006 which is commonly assigned with the present invention and incorporated herein by reference as if reproduced herein in its entirety.

### TECHNICAL FIELD

The present disclosure is directed, in general, to metal-metal interconnects and, more specifically, to a method for manufacturing an interconnect in a semiconductor device, a method for manufacturing a digital micromirror device, and a method for manufacturing a projection display system using the same.

### BACKGROUND

A Digital Micromirror Device (DMD) is a type of microelectromechanical systems (MEMS) device. Invented in 1987 at Texas Instruments Incorporated, the DMD is a fast, reflective digital light switch. It can be combined with image processing, memory, a light source, and optics to form a digital light processing® system capable of projecting large, bright, high-contrast color images.

The DMD is fabricated using CMOS-like processes over a CMOS memory. It has an array of individually addressable mirror elements, each having an aluminum mirror that can reflect light in one of two directions depending on the state of an underlying memory cell. With the memory cell in a first state, the mirror rotates to +12 degrees. With the memory cell in a second state, the mirror generally rotates to −12 degrees. By combining the DMD with a suitable light source and projection optics, the mirror reflects incident light either into or out of the pupil of the projection lens. Thus, the first state of the mirror appears bright and the second state of the mirror appears dark. Gray scale is achieved by binary pulse width modulation of the incident light. Color is achieved by using color filters, either stationary or rotating, in combination with one, two, or three DMD chips.

DMD's may have a variety of designs. However, the most popular design in current use is a structure consisting of a mirror that is rigidly connected to an underlying compliant torsion hinge. The hinge is coplanar with a beam structure comprising springtips that provide a mechanical means for stopping and starting the transition of the mirror from side to side. Electrostatic fields developed between the underlying memory cell and the mirror cause rotation in the positive or negative rotation direction.

The fabrication of the above-described DMD superstructure begins with a completed CMOS memory circuit. Through the use of photoresist layers, the superstructure is formed with alternating layers of aluminum for the address electrode, hinge, yoke, and mirror layers and hardened photoresist for sacrificial layers that form air gaps.

Unfortunately, during the aforementioned fabrication process non-conductive oxides tend to form on the surfaces of the layers of aluminum. When physical ablation, such as sputter cleaning, is not performed, the non-conductive oxide may lead to an increase in resistance and even capacitance at the junction between the separately deposited layers of aluminum. The increase in resistance may alter the timing of the circuit or have other undesirable effects.

Thus physical ablation would generally be desired. However, when the material isolating the aluminum layers is the hardened photoresist, such as in DMD superstructures, sputter cleaning is not possible without the plasma of the sputter cleaning process attacking the hardened photoresist. As this in also undesirable, sputter cleaning generally may not be used.

It should also be noted that similar problems may exist in conventional interconnects for semiconductor devices. While the conventional interconnects may not experience the drawback of not being able to sputter clean the non-conductive oxide, other problems exist.

Accordingly, what is needed in the art is a method for manufacturing a DMD, as well as an interconnect, that does not experience the drawbacks of the prior art methods.

### SUMMARY

To address the above-discussed deficiencies of the prior art, the present disclosure provides a method for manufacturing an interconnect in a semiconductor device, a method for manufacturing a digital micromirror device, a digital micromirror device and a method for manufacturing a projection display system. The method for manufacturing the interconnect in the semiconductor device, among others, may include the steps of forming a first metal layer over a substrate, and subjecting the first metal layer to an immersion deposition process, the immersion deposition process forming a passivating layer over the first metal layer. The method may further include contacting the passivating layer with a second metal layer.

Another aspect, as indicated above, is a method for manufacturing the digital micromirror device. The method for manufacturing the digital micromirror device, without limitation, may include forming a first metal layer over a substrate and subjecting the first metal layer to an immersion deposition process, the immersion deposition process forming a passivating layer over the first metal layer. This method may also include forming a spacer layer over the first metal layer, the spacer layer having one or more openings therein, and forming a second metal layer over the spacer layer and in the one or more openings, the second metal layer contacting the passivating layer.

In another embodiment, a digital micromirror device is provided. The digital micromirror device, without limitation, may include a first metal layer located over control circuitry located on or in a substrate, a passivating layer located on the first metal layer, and a second metal layer located over the first metal layer and contacting the passivating layer.

As briefly mentioned, also disclosed is a method for manufacturing a projection display system. This method, among other steps, may include: 1) providing a light source configured to produce a beam of light along a first light path, 2) positioning optics in the first light path, the optics configured to provide one or more color light beams, 3) forming one or more digital micromirror devices as described above, the digital micromirror devices configured to receive the color light beams from the optics, modulate the light on a pixel-by-pixel basis and reflect light from ON pixels along a second light path, 4) providing control electronics for receiving image data and controlling the light source and the modulation of the digital micromirror devices, 5) providing projection optics placed in the second light path magnifying and projecting an image on to a viewing screen, and 6) providing a light trap for receiving and discarding reflected light along a third light path coming from the OFF pixels on the digital micromirror devices.

### BRIEF DESCRIPTION OF THE DRAWINGS

For a more complete understanding of the present disclosure, reference is now made to the following descriptions taken in conjunction with the accompanying drawings, in which:

FIG. 1 illustrates a DMD at an initial stage of manufacture;

FIG. 2A illustrates the partially completed DMD illustrated of FIG. 1 after subjecting the first metal layer to an immersion deposition process, or so called immersion plating process;

FIG. 3A illustrates the partially completed DMD illustrated in FIG. 2A after forming a first spacer layer over the first metal layer, the first spacer layer having one or more openings therein;

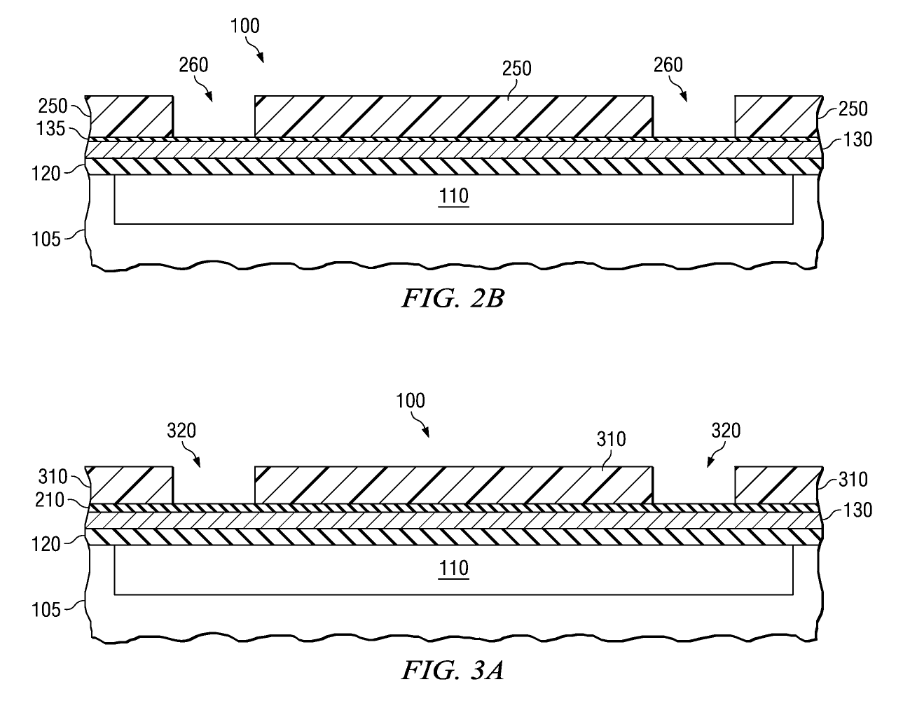

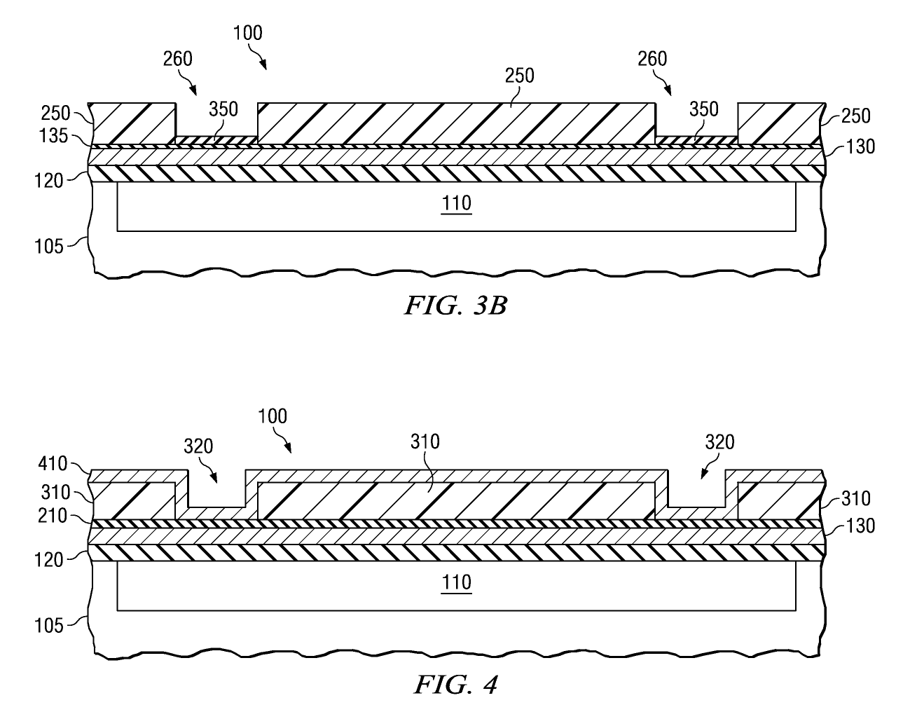

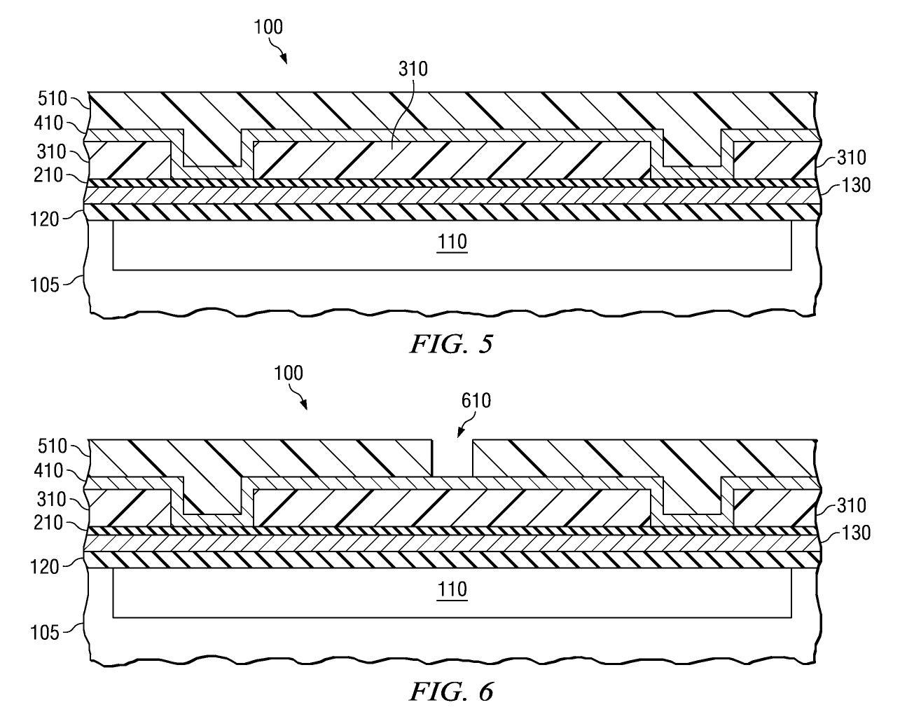

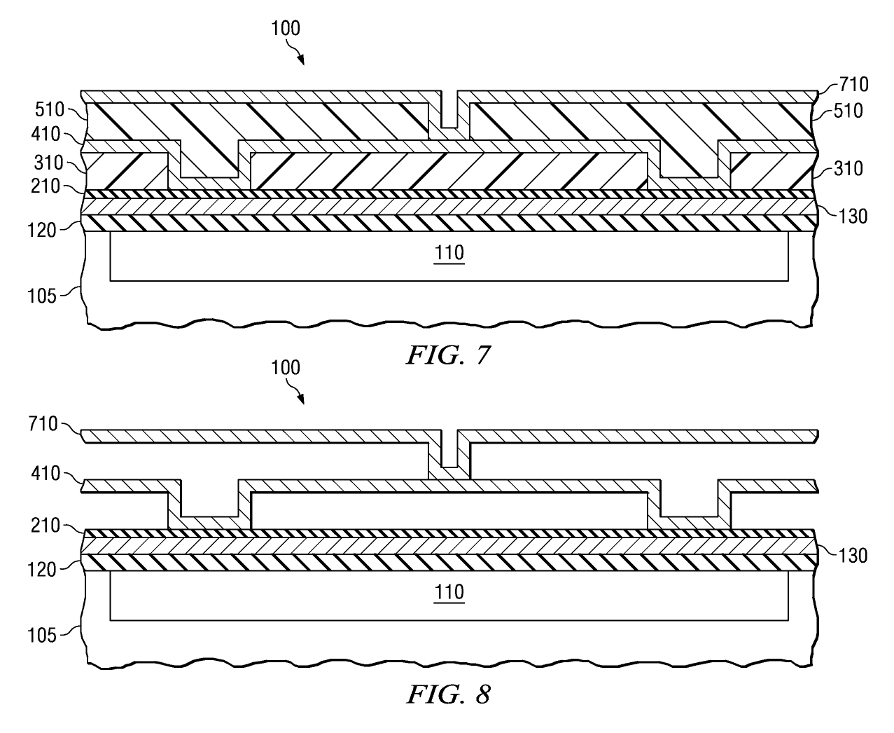

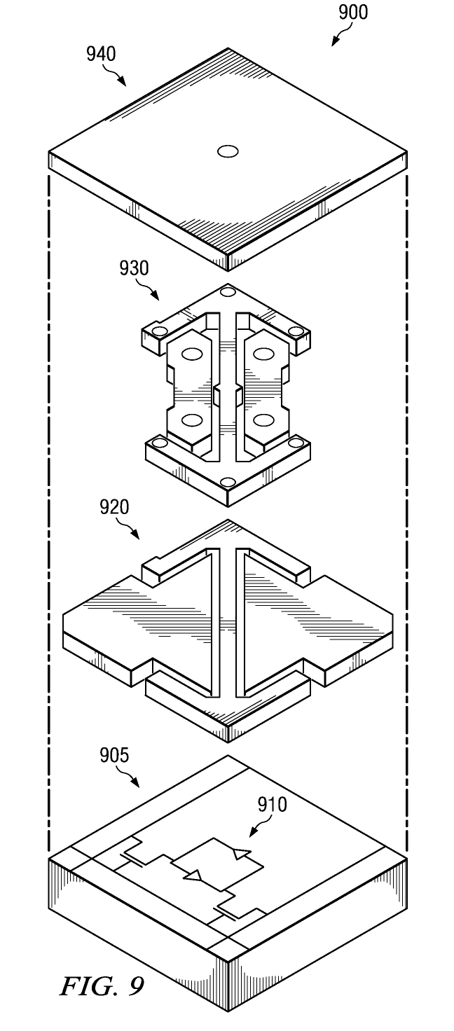

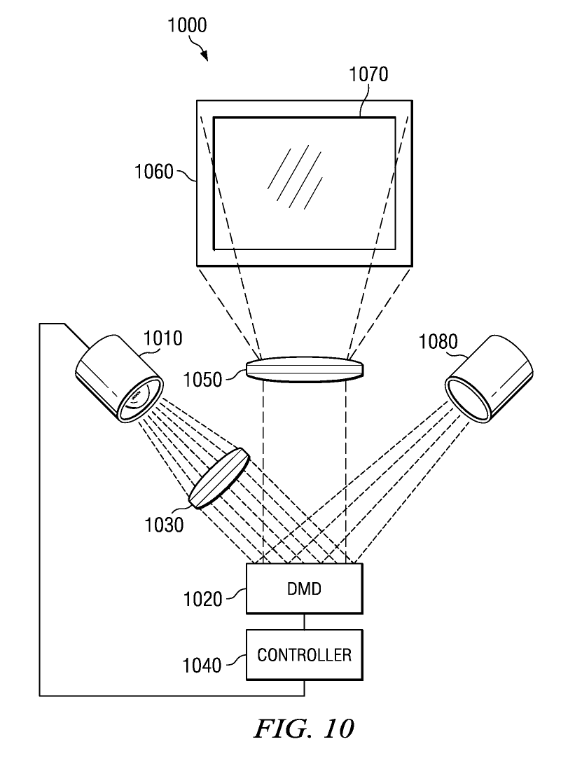

FIGS. 2B and 3B illustrate an alternative method for forming a passivating layer over the first metal layer and within openings in the photoresist layer;

FIG. 4 illustrates the partially completed DMD shown in FIG. 3A after contacting the passivating layer with a second metal layer;

FIG. 5 illustrates the partially completed DMD illustrated in FIG. 4 after patterning the second metal layer, and thereafter depositing a second spacer layer over the patterned second metal layer;

FIG. 6 illustrates the partially completed DMD illustrated in FIG. 5 after patterning an opening within the second spacer layer;

FIG. 7 illustrates the partially completed DMD illustrated in FIG. 6 after forming a third metal layer over the second spacer layer;

FIG. 8 illustrates the partially completed DMD illustrated in FIG. 7 after patterning the third metal layer and then removing the first spacer layer and the second spacer layer;

FIG. 9 illustrates an exploded view of a completed DMD manufactured in accordance with one embodiment; and

FIG. 10 illustrates a block diagram of a projection display system incorporating digital micromirror device(s) manufactured in accordance with one embodiment.

### DETAILED DESCRIPTION

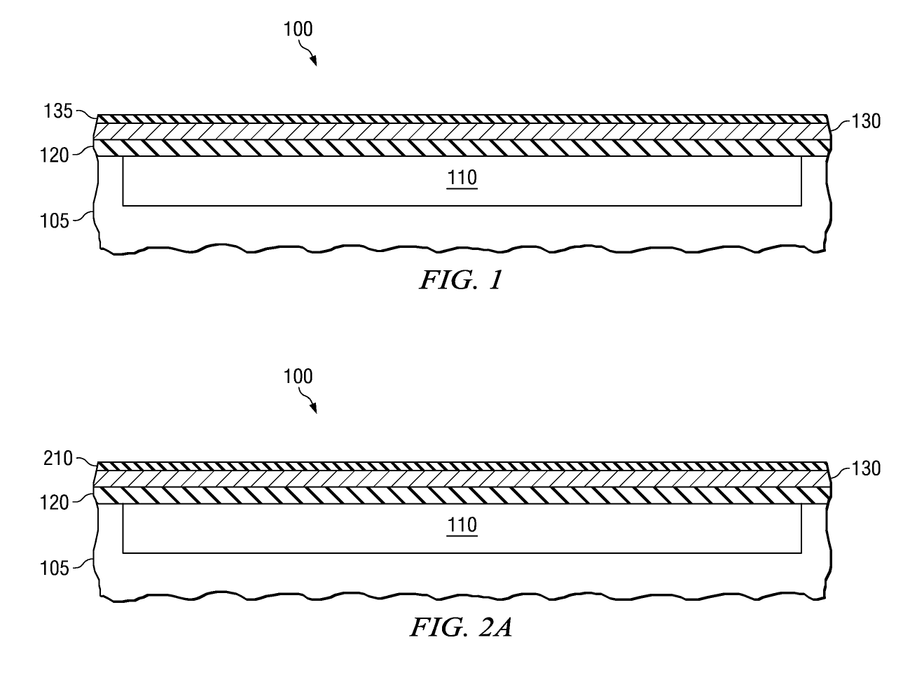

Turning to FIGS. 1-8, illustrated are cross-sectional views illustrating how one skilled in the art might manufacture a digital micromirror device (DMD) in accordance with one embodiment. While FIGS. 1-8 are specifically directed to the manufacture of a DMD, FIGS. 1-8 also illustrate, in one sense, how one skilled in the art might manufacture an interconnect used in a semiconductor device. Thus, a method for manufacturing an interconnect used in a semiconductor device is discussed within the confines of discussing how one skilled in the art might manufacture a DMD as shown in FIGS. 1-8. Nevertheless, while each of these ideas is discussed and illustrated using a single set of FIGS., neither should be limiting on the other.

FIG. 1 illustrates a DMD 100 at an initial stage of manufacture. The DMD 100 illustrated in FIG. 1 includes control circuitry 110 formed on or in a semiconductor substrate 105. The semiconductor substrate 105, in one embodiment, may comprise a number of different materials. In the embodiment illustrated in FIG. 1, however, the semiconductor substrate 105 is epitaxial silicon.

The control circuitry 110 may comprise a plurality of CMOS devices, for example, addressable SRAM circuits within the semiconductor substrate 105. Nevertheless, other embodiments may exist wherein additional or different circuitry may be included within the control circuitry 110 located on or in the semiconductor substrate 105.

The DMD 100 may further include an insulating layer 120 formed over the control circuitry 110. The insulating layer 120 may comprise an oxide, such as silicon oxide, that has been planarized by chemical mechanical planarization. Without being limited to such, the insulating layer 120 may have a thickness ranging from about 1 nm to about 10 nm. As the steps required to form the insulating layer 120 are conventional, no further detail is warranted.

Located over the insulating layer 120 is a first metal layer 130. The first metal layer 130, in certain embodiments, comprises a first oxidizable metal layer. For example, the first metal layer 130 may comprise aluminum or aluminum alloy that has been sputter deposited to a thickness ranging from about 100 nm to about 400 nm. While not shown in the illustrated cross-section, vias are formed in the insulating layer 130 to allow the first metal layer 130 to contact the underlying control circuitry 110 where necessary. While also not shown in the illustrated cross-section, the first metal layer 130 is patterned, resulting in electrode pads and a bias bus. The first metal layer 130, in one embodiment, is patterned by plasma-etching using plasma-deposited silicon dioxide as the etch mask.

As is often the case, the first metal layer 130 undesirably includes a first metal oxide layer 135 located thereon. The first metal oxide layer 135 generally forms on the first metal layer 130 during conventional processing steps, such as those processing steps including oxygen therein. The first metal oxide layer 135 may comprise various different thicknesses. However, in most situations the first metal oxide layer 135 has a thickness of about 5 nm or less. In many situations, the first metal oxide layer 135 is non-conductive. In those situations wherein the first metal oxide layer 135 is non-conductive or only slightly conductive, the first metal oxide layer 135 may lead to an increase in resistance and/or capacitance at the junction between the first metal layer 130 and the second metal layer 410 (FIG. 4).

FIG. 2A illustrates the DMD 100 of FIG. 1, after subjecting the first metal layer 130 to an immersion deposition process, or so called immersion plating process. The immersion deposition process, like electroless plating, does not employ an electric current. The immersion deposition process, which is sometimes also called galvanic plating, is an electrochemical displacement reaction that depends on the position that the substrate metal, in this example the first metal layer 130, occupies in the electromotive series with respect to the metal to be deposited from solution. Deposition occurs when the metal from a dissolved metal salt is displaced by a more active (less noble metal) that is immersed in the solution. Metal from the dissolved salt displaces a thin layer of metal at the surface of the immersed part, with the displaced metal dissolving in (and contaminating) the solution.

What may result from the immersion deposition process is a passivating layer 210 formed over the first metal layer 130, as is illustrated in FIG. 2A. As is illustrated, the immersion deposition process may remove at least a portion, if not all, of the first metal oxide layer 135, and deposits the passivating layer 210 on the first metal layer 130. In the disclosed embodiment wherein the first metal layer 130 comprises aluminum or aluminum alloy, the passivating layer 210 may comprise any material that is further down the electromotive series than aluminum, and thus any material that is reducible by the first metal layer 130. Accordingly, in certain embodiments the passivating layer 210 comprises zinc or tin. Nevertheless, the passivating layer 210 may comprise other materials along the electromotive series scale.

In one embodiment, dopant ions may be added to the main constituents of the immersion deposition process. The dopant ions may be added in any proportion to the main constituents of the immersion deposition process for a variety of purposes. For example, the dopant ions might be added for film stabilization, enhanced oxide conductivity (see below), etc.

The thickness of the resulting passivating layer 210 depends on a variety of factors. For example, the thickness of the passivating layer 210 may depend on the material composition of both the first metal layer 130 and the passivating layer 210, and thus the interaction there between. The thickness of the passivating layer 210 may further depend on the RMS surface roughness of the first metal layer 130. Nevertheless, in the embodiment wherein the first metal layer 130 comprises aluminum or aluminum alloy and the passivating layer 210 comprises zinc, the thickness of the passivating layer 210 should range from about 2 nm to about 4 nm. Other thicknesses may also be used.

In an optional step, not shown, the passivating layer 210 may be intentionally or unintentionally oxidized after finishing the immersion deposition process, thus forming an oxidized passivating layer over the passivating layer 210. For example, the passivating layer 210 may either be subjected to intentional processing steps to form a thin oxidized passivating layer thereover, or in another instance come into contact with ambient oxygen and oxidize on its own. By choosing a suitable passivating layer 210 material, the oxidized passivating layer may be a semiconductor or a conductor, rather than an insulator, such as is the case with the aluminum oxide layer 135 previously discussed. Zinc and tin, among others, are materials that form semiconducting oxides.

FIG. 3A illustrates the DMD 100 of FIG. 2A after forming a first spacer layer 310 over the first metal layer 130, the first spacer layer 310 having one or more openings 320 therein. The first spacer layer 310, in one embodiment, is a first layer of photoresist. For example, the first layer of photoresist may be formed by spin depositing a blanket layer of photoresist to a thickness ranging from about 400 nm to about 1500 nm. The first layer of photoresist may then be deep UV hardened to a temperature of about 200° C. to prevent flow and bubbling during subsequent processing steps. As those skilled in the art understand, the first spacer layer 310 in the DMD 100 illustrated in FIG. 3A is configured to provide a planar surface on which to build subsequent layers (e.g., the hinge), and to provide a gap between the hinge and the electrode pads and bias bus located there under.

Conventional patterning and etching techniques may be used to form the one or more openings 320 in the first spacer layer 310. For example, in the embodiment wherein the first spacer layer 310 is a first layer of photoresist, the openings 320 may be patterned into the first layer of photoresist by exposing, patterning, developing and then descuming the first layer of photoresist.

FIGS. 2B and 3B illustrated an alternative method for forming a passivating layer over the first metal layer and within openings in the photoresist layer. FIG. 2B illustrates that a first spacer layer 250 may be formed over the first metal layer 130, and in this embodiment the first metal oxide layer 135, the first spacer layer 250 having one or more openings 260 therein. The first spacer layer 250 having the one or more openings 260 may be formed in a similar fashion to the previously discussed first spacer layer 310. Thereafter, as is illustrated in FIG. 3B, the DMD 100 of FIG. 2B may be subjected to the immersion deposition process. In this embodiment, the immersion deposition process only contacts the portions of the first metal layer 130, and thus first metal oxide layer 135, that are exposed by the openings 260 in the first spacer layer 250. Accordingly, the passivating layer 350 forms over the portions of the first metal layer 130 exposed by the openings 260 in the spacer layer 250. The immersion deposition process used in FIG. 3B may be conducted in a similar fashion as the immersion deposition process discussed previously with respect to FIG. 2A.

In essence, the embodiments of FIGS. 2A and 3A are conducted such that the immersion deposition process is applied to the entire first metal layer 130, and then the first spacer layer 310 is formed thereover. In contrast, the embodiments of FIGS. 2B and 3B are conducted such that the first spacer layer 250 is formed having openings 260 therein, and then the portions of the first metal layer 130 exposed by the openings 260 are subjected to the immersion deposition process. Depending on the circumstances, as well as the desires of the manufacturer, one method may be more advantageous than the other.

FIG. 4 illustrates the DMD 100 of FIG. 3A after contacting the passivating layer 210 with a second metal layer 410. As is illustrated in the embodiment of FIG. 4, the second metal layer 410 is formed over and within the openings 320 in the first spacer layer 310, thus contacting the passivating layer 210. The second metal layer 410 may also be referred to as a hinge or binge metal layer. The second metal layer 410 may be formed using similar procedures and materials as described above for the first metal layer 130. The second metal layer 410 typically has a desirable thickness ranging from about 30 nm to about 100 nm.

In a step not illustrated in FIG. 4, an optional via plug may be deposited over the surface of the second metal layer 410. For example, a thick (e.g., around 500 nm) oxide could be blanket deposited over the entire surface of the second metal layer 410. Thereafter, a via plug etch-back could be performed, thus leaving a layer of via plug material along the sidewalls of the second metal layer 410 located in the openings 320. It is believed that the remaining via plug material provides structural support for the DMD 100.

While not illustrated in the embodiment of FIG. 4, at this point in the manufacturing process a second metal oxide layer might form over the second metal layer 410. This is particularly the circumstance if the second metal layer 410 is a second oxidizable metal layer. Understanding that a third metal layer may ultimately contact the second metal layer 410, in certain embodiments it might be desirable to subject the second metal layer 410 to the immersion deposition process discussed above. As one skilled in the art would expect, this immersion deposition process could remove part or all of the second oxidizable metal layer and then deposit a second passivating layer over the second metal layer 410. It should be noted that certain embodiments may exist wherein the immersion deposition process is subjected to the second metal layer 410 rather than the first metal layer 130, as opposed to in addition to the first metal layer 130. However, this would typically depend on the circumstances, as well as the desires of the manufacturer.

FIG. 5 illustrates the DMD 100 of FIG. 4 after patterning the second metal layer 410, and thereafter depositing a second spacer layer 510 over the patterned second metal layer 410. A hinge, as well as a spring, often results from the patterning process. While the patterned features in the second metal layer 410 (e.g., the hinge and the spring) are not illustrated in the cross-sectional view illustrated in FIG. 5, those skilled in the art understand that such features do indeed exist. As those skilled in the art appreciate, an etch mask, such as a plasma-deposited silicon dioxide etch mask, may be formed over the second metal layer 410 to assist in the etching of the second metal layer 410 to form the hinge and/or springs.

After patterning the second metal layer 410, the second spacer layer 510 may be deposited thereover. The second spacer layer 510, in the embodiment of FIG. 5, comprises a second layer of photoresist. Accordingly, similar procedures and materials may be used to form the second spacer layer 510 as described for the first spacer layer 310. As those skilled in the art appreciate, the second spacer layer 510 provides a planar surface on which to build subsequent layers, such as the mirror layer.

FIG. 6 illustrates the DMD 100 of FIG. 5 after patterning an opening 610 within the second spacer layer 510. In the embodiment of FIG. 6, the opening 610 is patterned in a center of the second spacer layer 510 using a process similar to that used to pattern the openings 320 in the first spacer layer 310. Accordingly, conventional patterning and etching steps may be used.

FIG. 7 illustrates the DMD 100 of FIG. 6 after forming a third metal layer 710 over the second spacer layer 510. In the embodiment of FIG. 7, the third metal layer 710 is deposited on the second spacer layer 510, as well as in the opening 610 in the second spacer layer 510. The third metal layer 710 may have a thickness ranging from about 200 nm to about 500 nm. Nevertheless, other thicknesses outside of the aforementioned range may be used. In one embodiment the third metal layer 710 is formed using similar procedures and materials as described above for the second metal layer 410.

FIG. 8 illustrates the DMD 100 of FIG. 7 after patterning the third metal layer 710 and then removing the first spacer layer 310 and the second spacer layer 510. As those skilled in the art appreciate, an etch mask, such as a plasma-deposited silicon dioxide etch mask, may be used to assist in the etching of the third metal layer 710. What results is an array of reflective surfaces or mirrors.

The removal of the first spacer layer 310 and of the second spacer layer 510 may be conventional. For example, a conventional plasma ashing or other similar process may be used to remove the first spacer layer 310 and the second spacer layer 510. Nevertheless, other known or hereafter discovered processes could also be used.

FIG. 9 illustrates a completed DMD 900 manufactured in accordance with one embodiment. The DMD 900 illustrated in FIG. 9 includes, among other elements, a semiconductor substrate 905 having control circuitry 910 located therein, a patterned first metal layer 920 located over the control circuitry 910, a patterned second metal layer 930 located over the patterned first metal layer 920, and a patterned third metal layer 940 located over the patterned second metal layer 930. The semiconductor substrate 905, control circuitry 910, patterned first metal layer 920, patterned second metal layer 930, and patterned third metal layer 940 are similar or slight variations of the semiconductor substrate 105, control circuitry 110, patterned first metal layer 130, patterned second metal layer 410, and patterned third metal layer 710, respectively, illustrated in FIG. 8.

The method for manufacturing an interconnect in a semiconductor device, or a DMD, as illustrated in FIGS. 1-8, provides various advantages over prior art methods. For example, the method allows for the ability to remove unwanted (e.g., non-conductive) oxide layers that may interpose two metal features or interconnects without being detrimental to the core aspects of the manufacturing process. As one example, the method allows the oxides to be removed from the various different metal layers in a DMD without sacrificing the integrity of the hardened photoresist layers used for their manufacture. Accordingly, DMD's having lower resistance and/or lower capacitance, thereby resulting in improved electrical contact and reliability, may be manufactured.

FIG. 10 illustrates a block diagram of a projection display system 1000 incorporating digital micromirror device(s) manufactured in accordance with one embodiment. In the projection display system illustrated in FIG. 10, illumination from a light source 1010 is focused on to the surface of one or more DMD(s) 1020 by means of a condenser lens 1030 placed in the path of the light. An electronic controller 1040 is connected to both the DMD(s) 1020 and the light source 1010 and used to modulate the DMD(s) 1020 and to control the light source 1010.

For all DMD pixels in the ON state, the incoming light beam is reflected into the focal plane of a projection lens 1050, where it is magnified and projected on to a viewing screen 1060 to form an image 1070. On the other hand, DMD pixels in the OFF state, as well as any stray light reflected from various near flat surfaces on and around the DMD, are reflected into a light trap 1080 and discarded.

Those skilled in the art to which the disclosure relates will appreciate that other and further additions, deletions, substitutions and modifications may be made to the described embodiments without departing therefrom.

What is claimed is:

1. A method for manufacturing an interconnect in a semiconductor device, comprising:
forming a first metal layer over a substrate;
subjecting the first metal layer to an immersion deposition process, the immersion deposition process forming a passivating layer over the first metal layer; and
contacting the passivating layer with a second metal layer.

2. The method as recited in claim 1 wherein forming a first metal layer includes forming a first oxidizable metal layer.

3. The method as recited in claim 2 wherein forming a first oxidizable metal layer further includes forming a first metal oxide layer over the first oxidizable metal layer.

4. The method as recited in claim 3 wherein subjecting the first metal layer to an immersion deposition process includes subjecting the first oxidizable metal layer and the first metal oxide layer to an immersion deposition process.

5. The method as recited in claim 4 wherein the immersion deposition process removes at least a portion of the first metal oxide layer before depositing the passivating layer over the first oxidizable metal layer.

6. The method as recited in claim 5 wherein the immersion deposition process removes all of the first metal oxide layer before depositing the passivating layer over the first oxidizable metal layer.

7. The method as recited in claim 1 wherein metal ions used to form the passivating layer are reducible by the first metal layer.

8. The method as recited in claim 7 wherein the first metal layer comprises aluminum and the metal ions include zinc or tin metal ions.

9. The method as recited in claim 1 wherein the passivating layer includes an oxidized passivating layer, the oxidized passivating layer being a semiconductor or a conductor.

10. The method as recited in claim 1 wherein contacting the passivating layer with a second metal layer includes contacting the passivating layer with a second metal layer through an opening in an insulative material.

11. A method for manufacturing a digital micromirror device, comprising:
forming a first metal layer over a substrate;
subjecting the first metal layer to an immersion deposition process, the immersion deposition process forming a passivating layer over the first metal layer;
forming a spacer layer over the first metal layer, the spacer layer having one or more openings therein; and
forming a second metal layer over the spacer layer and in the one or more openings, the second metal layer contacting the passivating layer.

12. The method as recited in claim 11 wherein subjecting the first metal layer to an immersion deposition process includes subjecting the first metal layer to an immersion deposition process through the one or more openings in the spacer layer.

13. The method as recited in claim 11 wherein the subjecting occurs before forming the spacer layer.

14. The method as recited in claim 11 wherein the first metal layer forms at least a portion of electrode pads or a bias bus and the second metal layer forms at least a portion of a hinge for the digital micromirror device.

15. The method as recited in claim 11 wherein the first metal layer forms at least a portion of a hinge for the digital micromirror device and the second metal layer forms at least a portion of a mirror for the digital micromirror device.

16. The method as recited in claim 11 wherein forming a first metal layer includes forming a first oxidizable metal layer having a first metal oxide layer formed thereover.

17. The method as recited in claim 16 wherein the immersion deposition process removes at least a portion of the first metal oxide layer before depositing the passivating layer over the first oxidizable metal layer.

18. The method as recited in claim 11 wherein metal ions used to form the passivating layer are reducible by the first metal layer.

19. The method as recited in claim 18 wherein the first metal layer comprises aluminum and the metal ions include zinc or tin metal ions.

20. A digital micromirror device, comprising:
a first metal layer located over control circuitry located on or in a substrate;
a passivating layer located on the first metal layer; and
a second metal layer located over the first metal layer and contacting the passivating layer.

21. The digital micromirror device as recited in claim 20 wherein the first metal layer forms at least a portion of electrode pads or a bias bus and the second metal layer forms at least a portion of a hinge for the digital micromirror device, and further including a reflective surface formed over the second metal layer.

22. The digital micromirror device as recited in claim 20 wherein the first metal layer forms at least a portion of a hinge for the digital micromirror device and the second metal layer forms at least a portion of a reflective surface for the digital micromirror device.

23. The digital micromirror device as recited in claim 20 wherein the passivating layer is only located on the first metal layer where the second metal layer electrically contacts the first metal layer.

24. The digital micromirror device as recited in claim 20 wherein the first metal layer is a first oxidizable metal layer.

25. The digital micromirror device as recited in claim 24 wherein the first metal layer comprises aluminum.

26. The digital micromirror device as recited in claim 20 wherein the passivating layer is an oxidized passivating layer, the oxidized passivating layer being a semiconductor or a conductor.

27. The digital micromirror devices as recited in claim 20 wherein the passivating layer comprises any material that is further down an electromotive series than the first metal layer.

28. A method for manufacturing a projection display system, comprising:
providing a light source configured to produce a beam of light along a first light path;
positioning optics in the first light path, the optics configured to provide one or more color light beams;
forming one or more digital micromirror devices configured to receive the color light beams from the optics, modulate the light on a pixel-by-pixel basis and reflect light from ON pixels along a second light path, including:
forming a first metal layer over a substrate;
subjecting the first metal layer to an immersion deposition process, the immersion deposition process forming a passivating layer over the first metal layer;
forming a spacer layer over the first metal layer, the spacer layer having one or more openings therein; and
forming a second metal layer over the spacer layer and in the one or more openings, the second metal layer contacting the passivating layer;
providing control electronics for receiving image data and controlling the light source and the modulation of the digital micromirror devices; and
providing projection optics placed in the second light path magnifying and projecting an image on to a viewing screen.
